(19) United States
(12) Patent Application Publication
(10) Pub. No.: US 2014/0120735 A1
(43) Pub. Date: May 1, 2014

(54) SEMICONDUCTOR PROCESS GAS FLOW CONTROL APPARATUS

(71) Applicant: MACRONIX INTERNATIONAL CO., LTD., Hsinchu (TW)

(72) Inventors: Shing Ann LUO, Tonfene City (TW); Yung Tai HUNG, Chiayi City (TW); Chin-Ta SU, Yunlin Country (TW)

(73) Assignee: MACRONIX INTERNATIONAL CO., LTD., Hsinchu (TW)

(21) Appl. No.: 13/664,610

(22) Filed: Oct. 31, 2012

(51) Int. Cl. H01L 21/30

(52) U.S. Cl. 438/758; 118/728; 118/730; 257/E21.211

(57) ABSTRACT

A semiconductor processing apparatus includes a process chamber, a pedestal and a showerhead. The pedestal is inside the process chamber and holds a semiconductor wafer. The showerhead supplies process gas to the process chamber.

### BACKGROUND

The present application relates generally to semiconductor devices and includes methods and apparatus for improving uniformity of deposition and/or concentration of material on a semiconductor wafer.

An important capability for manufacturing reliable integrated circuits is to uniformly treat a semiconductor wafer. If, in a process step, a treatment is applied unevenly to the wafer, a difference in thickness of deposited material or concentration (e.g., Boron, Phosphorus, Nitrogen, or another dopant concentration) may occur across the wafer. These differences may cause device defects or require additional process steps to correct. For example, if a deposition is not uniform, a longer or more aggressive chemical mechanical planarization (CMP) step may be required. As another example, if a certain Boron, Phosphorus, Nitrogen, or other dopant concentration is specified, non-uniform concentrations may result in inoperable or otherwise unacceptable devices at some locations on the wafer resulting in lower production yield and higher device cost. With the reduction in size of semiconductor devices, increase in size of wafers and desire for higher production yields, these differences are a significant issue and improved uniformity is desired.

### BRIEF SUMMARY

According to one embodiment, a semiconductor processing apparatus includes a process chamber, a pedestal and a showerhead. The pedestal is inside the process chamber and holds a semiconductor wafer. The showerhead supplies process gas to the process chamber. The showerhead has a plurality of controllable outlets that supply one or more process gases to the process chamber.

According to another embodiment, a semiconductor processing apparatus includes a process chamber, a pedestal and a showerhead. The pedestal is inside the process chamber and holds a semiconductor wafer. The showerhead supplies process gas to the process chamber. The pedestal is rotatable while gas flows through the outlets of the showerhead.

According to another embodiment, a semiconductor processing apparatus includes a process chamber, a pedestal and a showerhead. The pedestal is inside the process chamber and holds a semiconductor wafer. The showerhead supplies process gas to the process chamber. The showerhead has a plurality of controllable outlets that supply one or more process gases to the process chamber. The pedestal is rotatable while gas flows through the outlets of the showerhead.

According to another embodiment, a method for processing a semiconductor wafer includes: providing a semiconductor wafer on a pedestal; supplying a process gas to the semiconductor wafer to perform a process step; and controlling the supply of the process gas to the semiconductor wafer to improve uniformity of the process step.

### BRIEF DESCRIPTION OF THE DRAWINGS

FIG. 1 is a side perspective view of the inside of an exemplary process chamber.

FIG. 2 is a bottom view of an exemplary showerhead.

FIG. 3A is a profile map of an exemplary deposition thickness.

FIG. 3B is a chart of an exemplary deposition thickness.

FIG. 4 is a side perspective view of the inside of an exemplary process chamber.

FIG. 5 is a bottom view of an exemplary showerhead.

FIG. 6 is a bottom view of an exemplary showerhead and a block diagram of an exemplary gas flow system.

FIG. 7 is a bottom view of an exemplary showerhead and a block diagram of an exemplary gas flow system.

FIG. 8 is a system diagram of an exemplary processing system.

FIG. 9 is a system diagram of an exemplary processing system.

FIG. 10 is a flow diagram of an exemplary calibration process.

### DETAILED DESCRIPTION

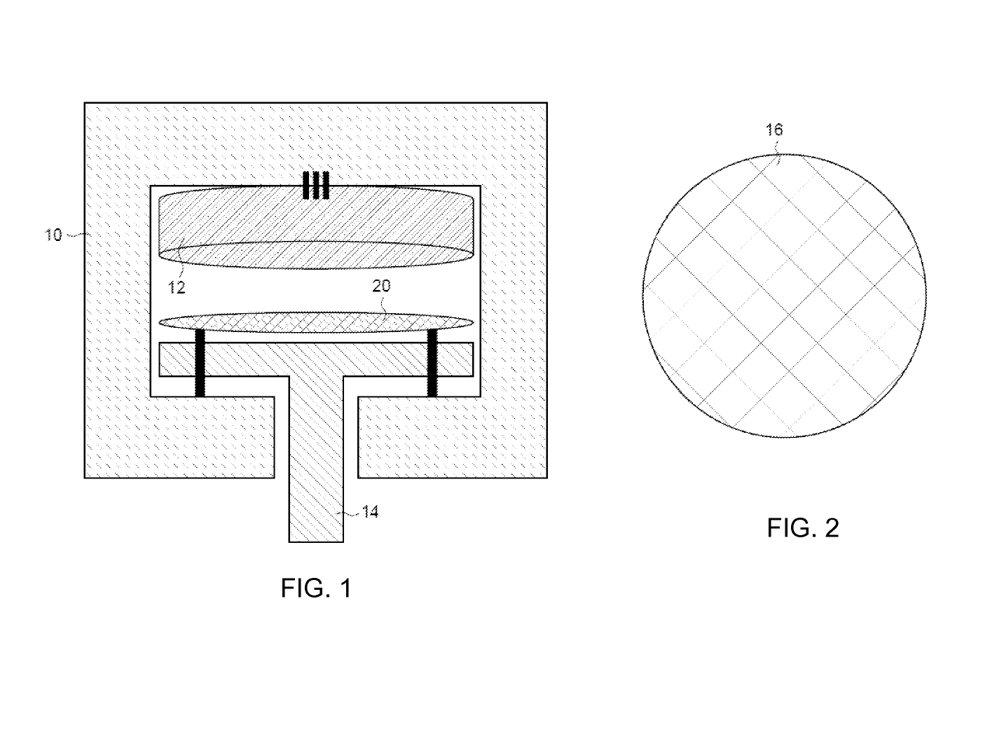

Referring to FIG. 1, a process chamber 10 includes a showerhead 12 and a pedestal 14. The showerhead 12 delivers process gas (such as a Tetraethyl orthosilicate (TEOS), Triethylborane (TEB) and TriEthylPhosphate (TEPO) mixture) to the process chamber 10. As shown in FIG. 2, the showerhead 12 may have a diffuser 16 to spread gas flow, but it is otherwise a static non-controllable device. It is connected to a singularly controlled gas supply that is in turn supplied to the showerhead 12.

The pedestal 14 is fixed in the process chamber 10 during a processing step and holds the semiconductor wafer 20 in a fixed location during the processing step. The pedestal 14 may be movable in the sense that sometimes moves the wafer 20 to the processing chamber 10, but it static and does not move during a semiconductor process.

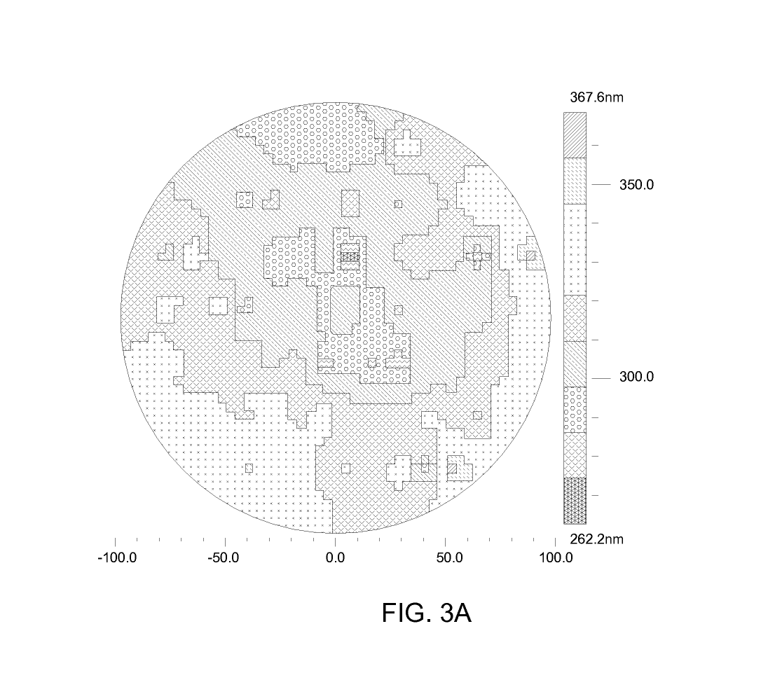

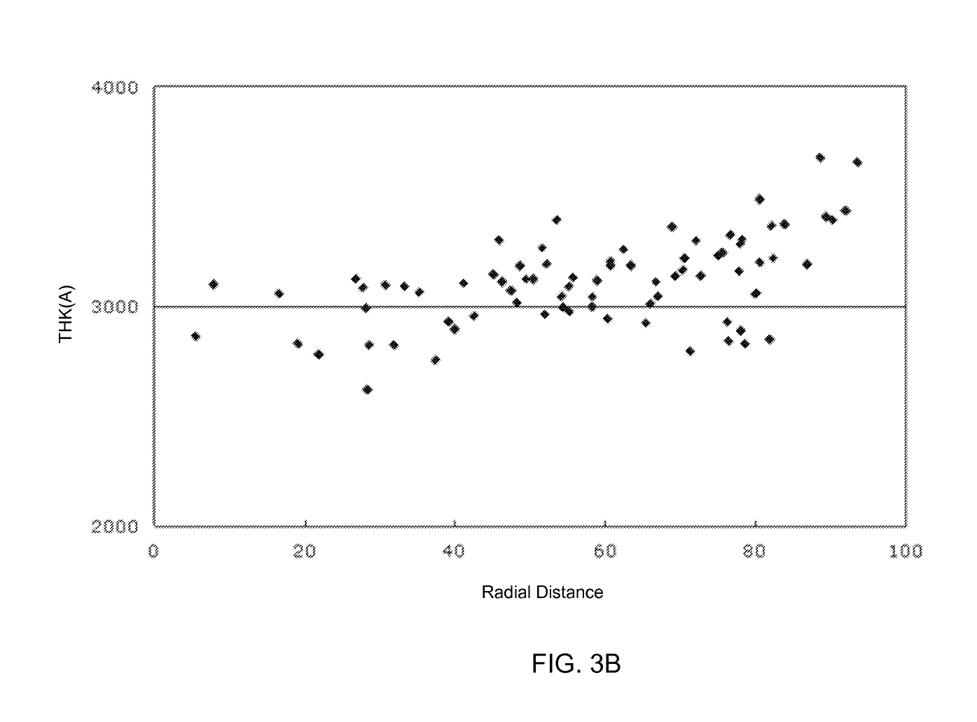

FIG. 3A shows an exemplary deposition thickness across a wafer following a deposition process in the process chamber 10. In this example, the deposition process was an oxide deposition such as a SiO₂ deposition. Notably, at a given radius, there are several different thicknesses of oxide. For example, near the lower left, the oxide is thinner than near the upper portion of the wafer at a given radial circumference.

FIG. 3B shows the thickness of the deposition at different radial distances from the center of the wafer. Near the edge of the wafer (right end of the graph) the average thickness of the oxide is significantly greater than the average thickness of the oxide near the center of the wafer (left end of the graph). There is a non-uniformity in average thickness between the center and edge of the wafer. This center to edge non-uniformity is a more significant issue and more difficult to control within a small window in the larger wafer sizes now being used in semiconductor fabrication than in the smaller wafers previously used. As can be seen in these figures, the deposition thickness is not uniform and varies more than 1000 A. Thus, the within wafer (WIW) uniformity is poor.

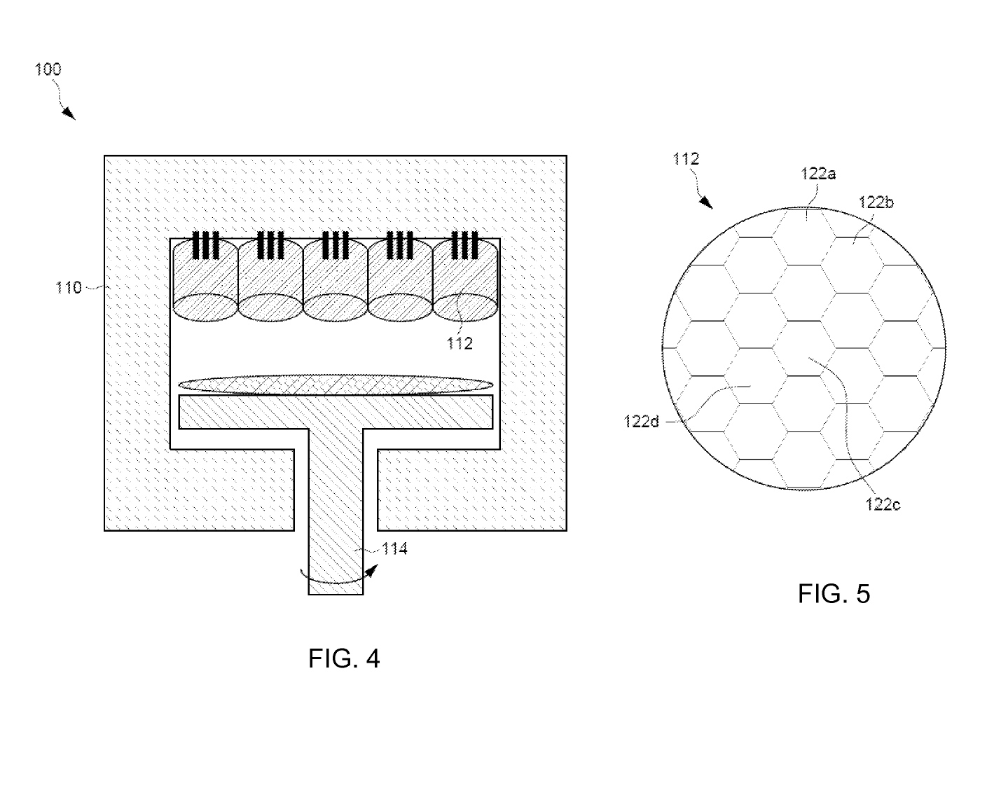

FIG. 4 shows an embodiment of a processing apparatus 100 having improved uniformity of deposition or concentration of delivered process gas. The processing apparatus 100 includes the process chamber 110. The process chamber 110 includes the multi-showerhead 112 and the spin pedestal 114. As shown in FIG. 5, the multi-showerhead 112 includes a plurality of outlets 122a, b, c, d, . . . (collectively the outlets 122). The plurality of outlets 122 provides for finer control of the delivery of process gas thereby allowing for the uniformity of the deposition or concentration applied to the wafer to be controlled. The spin pedestal 114 is rotatable during a process step. The rotation of the spin pedestal 114 allows for the uniformity of the deposition or concentration applied to the wafer to be controlled. Rotating the wafer during deposition allows for greater uniformity at a given radial circumference.

It will be appreciated that some embodiments may include one of the multi-showerhead 112 and the spin pedestal 114. That is, some embodiments may include the multi-showerhead 112, some embodiments may include the spin pedestal 114, and some embodiments may include both the multi-showerhead 112 and the spin pedestal 114.

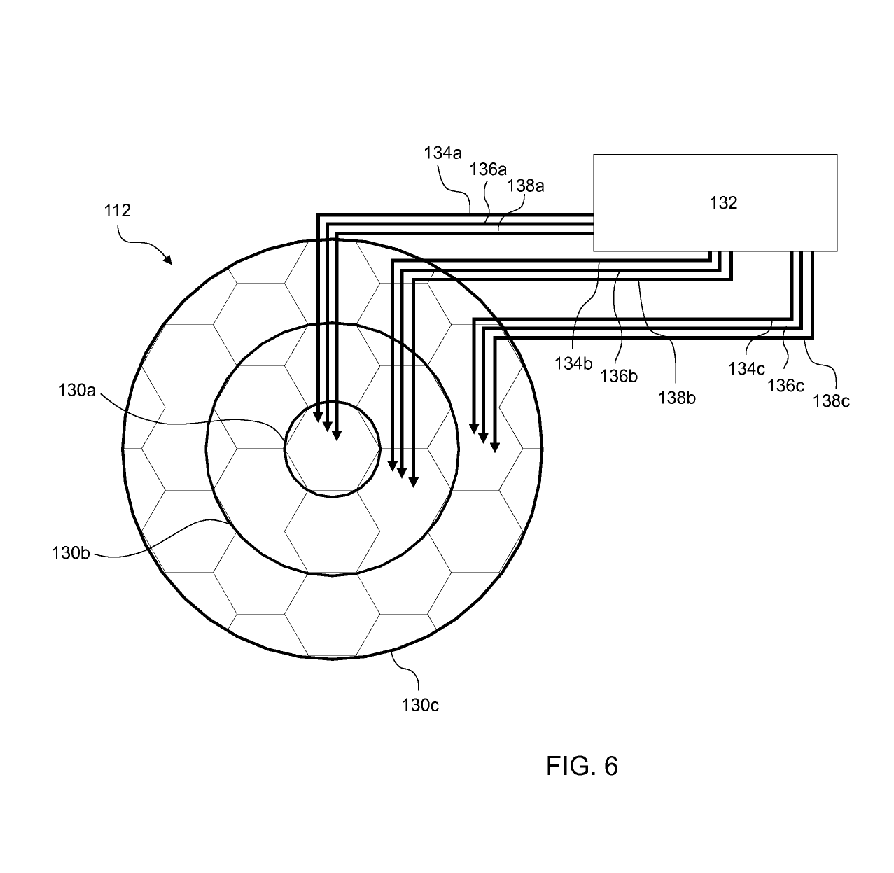

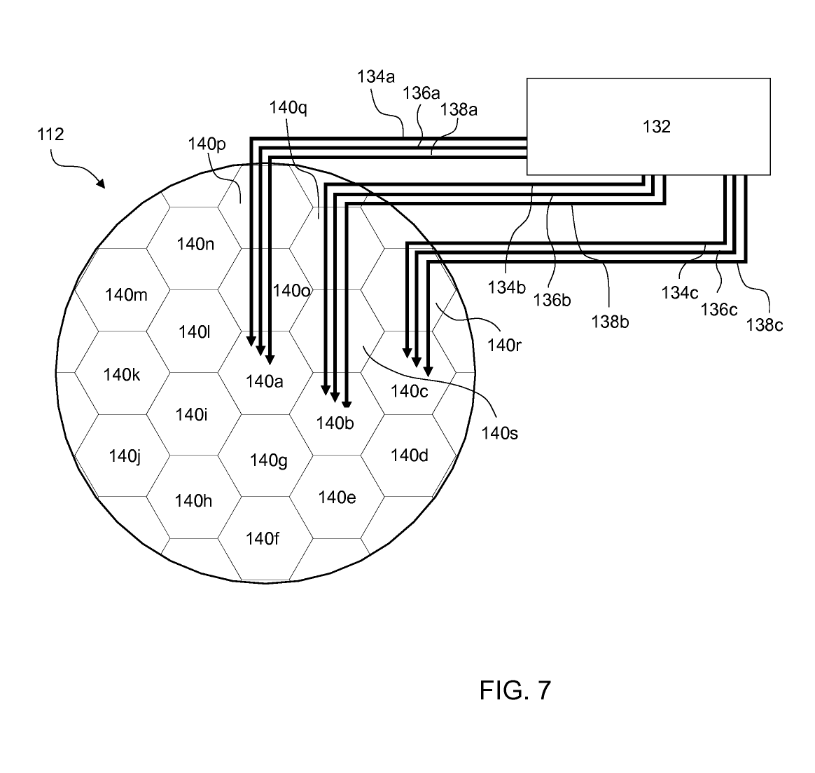

The number of outlets and control of the outlets 122 may be provided in a number of ways. The outlets may be controlled individually or they may be controlled in groups. For example, as shown in FIG. 6, the outlets 122 may be separated into a concentric zones 130a, 130b and 130c.

The use of concentric zones 130a, 130b and 130c allows for adjustment of the distribution of process gas between an edge and a center of a wafer while still maintaining a relativly simple and cost effective implementation. In combination with the rotating pedestal, which improves uniformity at a given radial distance, the concentric circle arrangement, which improves uniformity at different radiuses, synergistically improves uniformity across the entire wafer.

Each of the zones 130 may be individually supplied with process gases, such as TEOS, TEB, and TEPO, from a gas box 132 via lines 134a, 134b, 134c, 136a, 136b, 136c, 138a, 138b and 138c. Lines 134 supply a first process gas to zones 130, lines 136 supply a second process gas to zones 130 and lines 138 supply a third process gas to zones 130. In this manner, each of the process gases can be individually controlled within each of zones 130. In some embodiments, the processes gases may be supplied as a mixed gas to the zones 130 to reduce the number of control valves needed.

Referring to FIG. 7, in some embodiments, each outlet 140a . . . 140s of the multi-shower head 112 may be controlled individually. For simplicity, lines are shown to three of outlets 140, but lines may be provided individually to all of the outlets 140.

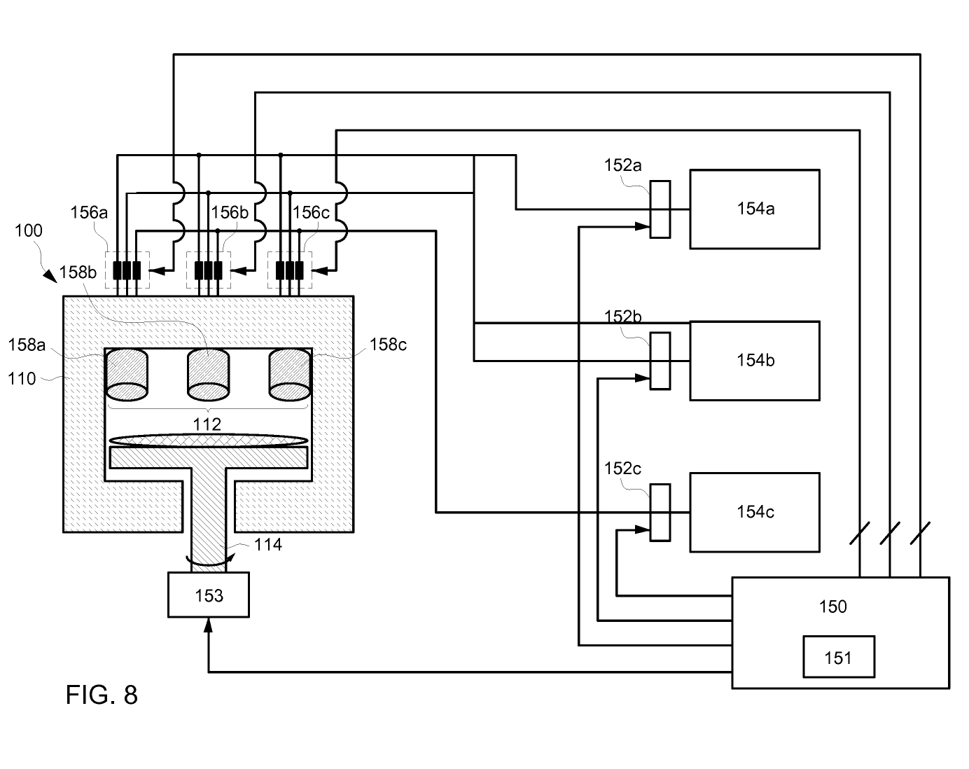

Referring to FIG. 8, the processing apparatus 100 may be controlled by a controller 150 to execute a processing step. The controller 150 may include a memory 151 for storing calibration information and processing instructions. The controller 150 may be a special purpose processor/computer or a general purpose processor programmed to execute the functions of the controller. The controller may also be provided in the form of computer executable instructions that, when executed by a processor, cause the processor to execute the functions of the controller. The computer executable instructions may be stored on one or more computer readable mediums (e.g., RAM, ROM, etc) in whole or in parts.

The controller 150 is connected to a motor 153 to control the rotation of the spin pedestal 114. The controller 150 is connected to supply valves 152a, 152b and 152c to control the supply of gas from gas supplies 154a, 154b and 154c respectively. The controller 150 is connected to supply valves 156a, 156b, and 156c to control the supply of gas to outlets 158a, 158b and 158c of multi-showerhead 112 respectively. Each of supply valves 154a, 154b and 154c includes a valve that individually controls one supply gas. That is, if there are three gas supplies and three outlets of the multi-showerhead, the supply valves 154a, 154b and 158c include a total of 9 valves. Independent control of each supply gas at each region allows for finer control of the process. For example, it may be measured that a certain region of the wafer has a non-optimal concentration of an element related to one of the supply gases. Allowing the manipulation of that supply gas locally to a region of the wafer provides for greater control of the process. The valves 152, 154, 156 and 158 may provide varied gas flow or they may provide discrete on/off control.

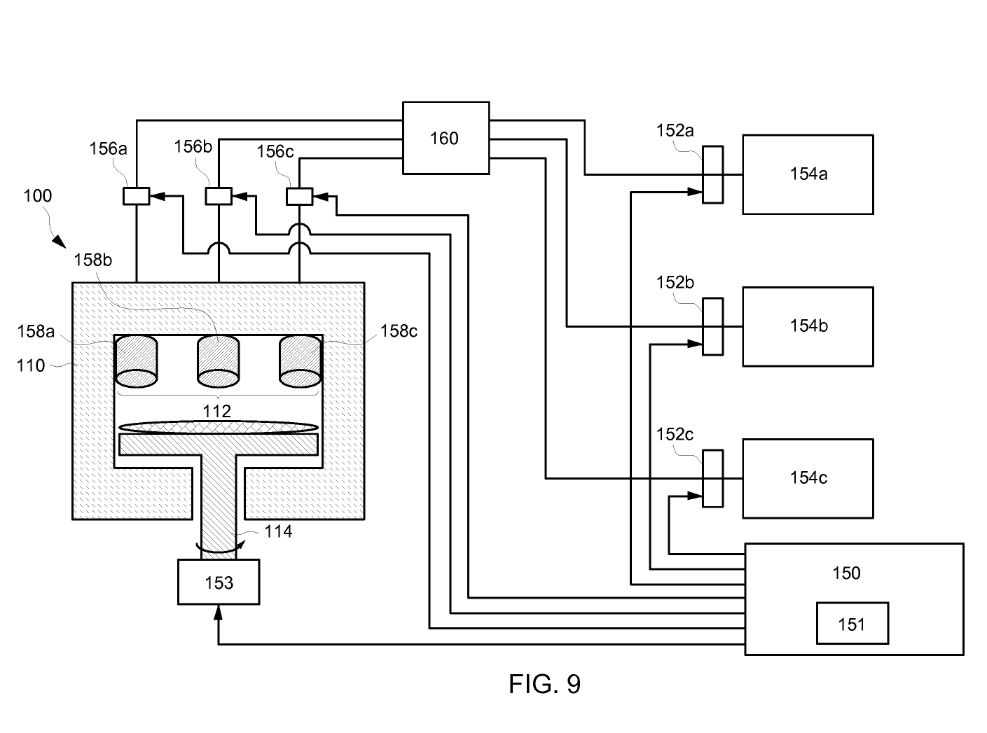

Referring to FIG. 9, the lines from gas supplies 154a, 154b, 154c may be joined at joining point 160 to supply a mixed gas to single supply valves 156a, 156b and 156c. The joining point 160 may be a chamber designed to mix the supply gases or it may be a pipe or other structure. Also, the supply gases may be joined in stages with some being joined at one point and others being joined at other points before reaching the supply valves 156.

As compared to the processing apparatus shown in FIG. 8, the processing device apparatus of FIG. 9 provides for a simpler and less costly implementation with fewer valves and fewer supply lines to arrange and install. It also provides a benefit when homogeneity of the supply gas mixture is preferred over individualized control of the supply gas mixture.

It will be appreciated that the embodiments shown in FIGS. 8 and 9 are exemplary in nature and various combinations of the two are contemplated. The exact arrangement and number of the supply valves and supply lines will depend on the design objectives of a specific implementation of the processing apparatus.

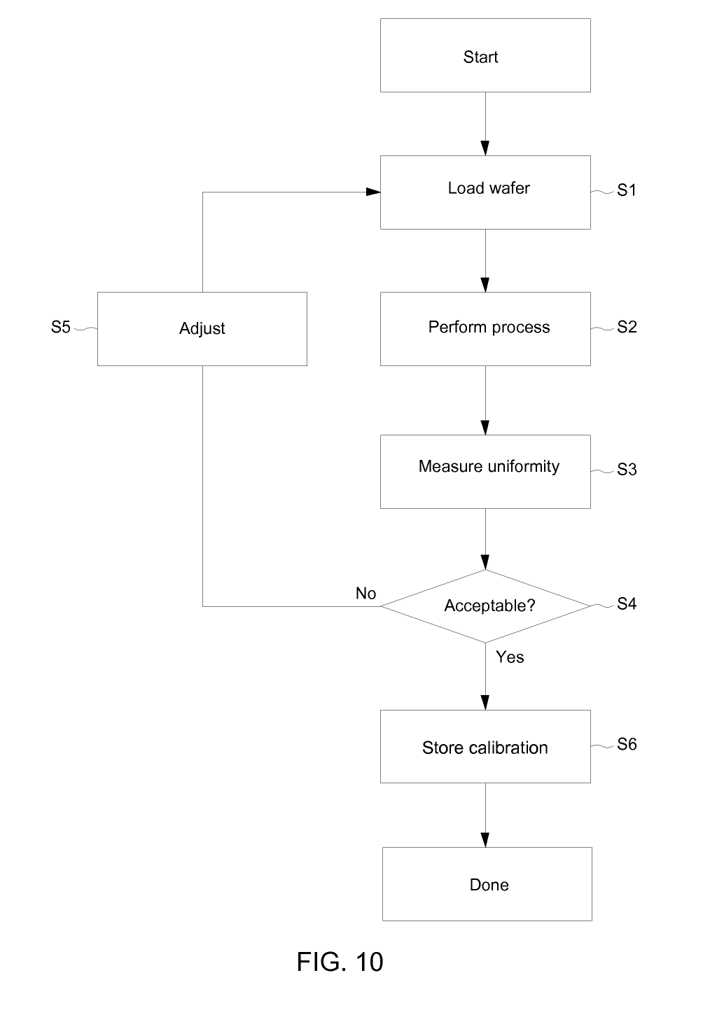

Referring now to FIG. 10, a method of calibrating the processing device 100 is described. At step S1, a wafer is loaded into the processing device 100, for example by positioning the pedestal 114 in its operating position or by placing the wafer on the pedestal 114. At step S2, a process step, such as an oxide deposition, is performed. At step 3, the uniformity of the performed process is measured. For example, when the process step is a deposition, the thickness of the deposition may be measured. At step S4, it is decided whether the uniformity is acceptable. If no, then the process advances to step S5. If yes, the process advances to step S6.

At step S5, the processing step is adjusted. For example, gas flow to zones of the multi-showerhead over thick areas may be reduced, gas flow to zones of the multi-showerhead over thin areas may be increased, and the rotation of the spin pedestal may be increased or decreased. The process then continues to step S1.

At step S6, the calibration (i.e., the gas flow to each of the zones of the multi-showerhead, rotation of the spin pedestal, etc) is stored and the process is completed.

With the calibration information stored, it can be referenced to improve the uniformity of processes performed by the processing apparatus.

Exemplary benefits of the above described semiconductor processing device include improved uniformity of concentration or thickness of a treatment applied to a semiconductor wafer. The described semiconductor processing device may be used for the deposition of oxides and other films (SiN, SiO₂, etc) as well as for controlling the concentration of Boron (B%), Phosphorus (P%), Nitrogen (N%) and other dopants in a processing step.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

1. A semiconductor processing apparatus, comprising:
a process chamber;
a pedestal inside the process chamber that holds a semiconductor wafer; and
a showerhead that supplies process gas to the process chamber, the showerhead having a plurality of controllable outlets that supply one or more process gases to the process chamber,
wherein the apparatus is operable to be calibrated by iteratively performing an operational process upon the semiconductor wafer and measuring a uniformity metric until the uniformity metric is within an acceptable threshold.

2. The semiconductor processing apparatus according to claim 1, wherein the controllable outlets are individually controllable.

3. The semiconductor processing apparatus according to claim 1, wherein the plurality of process gases are individually controllable.

4. The semiconductor processing apparatus according to claim 1, wherein
the showerhead includes a group of the outlets, the group including a number of outlets less than a total number of the outlets of the showerhead, and
the group of outlets are controllable at the same time as a set.

5. The semiconductor processing apparatus according to claim 1, further comprising a plurality of valves connected between a process supply line and the outlets of the showerhead, wherein the valves control the supply of process gas to the process chamber via the outlets.

6. The semiconductor processing apparatus according to claim 5, wherein the valves are variable valves that control an amount of gas flow.

7. The semiconductor processing apparatus according to claim 1, wherein the plurality of outlets include at least an inner outlet and an outer outlet around the inner outlet.

8. The semiconductor processing apparatus according to claim 1, wherein the pedestal is rotatable while gas flows through the outlets of the showerhead.

9. A semiconductor processing apparatus, comprising:
a process chamber;
a pedestal inside the process chamber that holds a semiconductor wafer; and
a showerhead that supplies process gas to the process chamber, wherein
the pedestal is rotatable while gas flows through the showerhead,
wherein the apparatus is operable to be calibrated by iteratively performing an operational process upon the semiconductor wafer and measuring a uniformity metric until the uniformity metric is within an acceptable threshold.

10. The semiconductor processing apparatus according to claim 9, wherein the pedestal is rotatable at variable speeds.

11. The semiconductor processing apparatus according to claim 9, further comprising a motor connected to the pedestal that rotates the pedestal.

12. The semiconductor processing apparatus according to claim 11, wherein the motor is a variable speed motor.

13. The semiconductor processing apparatus according to claim 9, wherein the showerhead includes a plurality of individually controllable outlets that supply one or more process gases to the process chamber.

14. The semiconductor processing apparatus according to claim 13, wherein the plurality of outlets include at least an inner outlet and an outer outlet around the inner outlet.

15. A semiconductor processing apparatus, comprising:
a process chamber;
a pedestal inside the process chamber that holds a semiconductor wafer; and
a showerhead that supplies process gas to the process chamber, the showerhead having a plurality of controllable outlets that supply one or more process gases to the process chamber,
wherein the pedestal is rotatable while gas flows through the outlets of the showerhead, and
wherein the apparatus is operable to be calibrated by iteratively performing an operational process upon the semiconductor wafer and measuring a uniformity metric until the uniformity metric is within an acceptable threshold.

16. The semiconductor processing apparatus according to claim 15, wherein the controllable outlets are individually controllable.

17. The semiconductor processing apparatus according to claim 15, wherein the plurality of outlets include at least two outlets arranged as an inner outlet and an outer outlet around the inner outlet.

18. The semiconductor processing apparatus according to claim 15, further comprising
a plurality of variable valves connected between a process supply line and the outlets of the showerhead, wherein
the variable valves control the supply of and amount of process gas to the process chamber via the outlets, and
the pedestal is rotatable at variable speeds.

19. A method for processing a semiconductor wafer, comprising:
providing a semiconductor wafer on a pedestal;
supplying a process gas to the semiconductor wafer to perform a process step; and
controlling the supply of the process gas to the semiconductor wafer to improve uniformity of the process step.

20. The method of claim 19, wherein the step of controlling includes rotating the pedestal while the process gas is being supplied to the semiconductor wafer.

21. The method of claim 19, wherein the step of supplying the process gas includes supplying the process gas via a showerhead that includes a plurality of controllable outlets that supply the process gas.

22. The method of claim 21, wherein the step of controlling includes controlling the plurality of outlets of the showerhead.

23. The method of claim 21, wherein the plurality of outlets include at least an inner outlet and an outer outlet around the inner outlet.
